(19) United States
(12) Patent Application Publication
(10) Pub. No.: US 2025/0391727 A1
(43) Pub. Date: Dec. 25, 2025

(54) SEMICONDUCTOR DEVICE

(71) Applicant: FUJI ELECTRIC CO., LTD., Kawasaki-shi (JP)

(72) Inventors: Takahito HARADA, Matsumoto-city (JP); Rikihiro MARUYAMA, Matsumoto-city (JP); Norihiro DAICHO, Matsumoto-city (JP)

(73) Assignee: FUJI ELECTRIC CO., LTD., Kawasaki-shi (JP)

(21) Appl. No.: 19/222,367

(22) Filed: May 29, 2025

(30) Foreign Application Priority Data
Jun. 21, 2024 (JP) 2024-100131

(51) Int. Cl. H01L 23/367; H01L 23/00; H01L 23/049; H01L 23/373

(52) U.S. Cl. CPC H01L 23/3672; H01L 23/049; H01L 23/3735; H01L 24/32; H01L 24/48; H01L 24/73; H01L 2224/32225; H01L 2224/48137; H01L 2224/48225; H01L 2224/73265

(57) ABSTRACT

A heat dissipation plate having a plate shape, and having a top surface and a bottom surface. At least the bottom surface has a center portion that protrudes in an upward direction at a center of the plate, and has a downward slope from the center portion to an outer edge of the plate, the top surface having the insulated circuit board bonded thereto. The heat dissipation plate has a fastening hole that penetrates the plate in a peripheral area. A peripheral portion of the bottom surface of the plate, provided between the outer edge and the fastening hole, is provided at a position downward relative to an inner portion of an opening edge of the fastening hole. The inner portion lies on a line passing through the center of the plate and a center of the fastening hole.

### CROSS-REFERENCE TO RELATED APPLICATION

This application is based upon and claims the benefit of priority of the prior Japanese Patent Application No. 2024-100131, filed on Jun. 21, 2024, the entire contents of which are incorporated herein by reference.

### BACKGROUND OF THE INVENTION

### 1. Field of the Invention

The embodiments discussed herein relate to a semiconductor device.

### 2. Background of the Related Art

Regarding a semiconductor device, insulated circuit boards on which semiconductor chips are bonded are disposed on a base plate. This base plate is fastened to a cooling unit with screws. The base plate is provided with protrusions so that the base plate will not be damaged when the base plate whose bottom surface has been warped into a convex shape facing downward is attached to the cooling unit (for example, see Japanese Laid-open Patent Publication No. 2018-195717, Publication of U.S. Patent Application No. 2008/0101032, Japanese Laid-open Patent Publication No. 2000-058727, and U.S. Pat. No. 9,929,066). Regarding another semiconductor device, a base plate is fastened to a cooling unit with screws, and escapes for the grease provided between the base plate and the cooling unit are formed around the screw holes in the base plate (for example, Japanese Laid-open Patent Publication No. 2006-165279).

### SUMMARY OF THE INVENTION

In one aspect of the embodiments, there is provided a semiconductor device including: an insulated circuit board; and a heat dissipation plate having a plate shape, having a top surface and a bottom surface, at least the bottom surface having a center portion that protrudes in an upward direction at a center of the heat dissipation plate, having a downward slope from the center portion to an outer edge of the heat dissipation plate, the top surface having a sloping area on which the insulated circuit board is bonded, the heat dissipation plate having a fastening hole that extends through the top surface and the bottom surface in a peripheral area of the heat dissipation plate, wherein a peripheral portion of the bottom surface of the heat dissipation plate, provided between the outer edge and the fastening hole, is provided at a position that is downward relative to an inner portion of an opening edge of the fastening hole, the inner portion of the opening edge lying on a line passing through the center of the heat dissipation plate and a center of the fastening hole.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side sectional view of a semiconductor device according to a first embodiment;

FIG. 2 is a plan view (a top surface) of a heat dissipation plate of the semiconductor device according to the first embodiment;

FIG. 3 is a side sectional view illustrating attachment of a semiconductor device according to a reference example to a cooling device;

FIG. 4 is a side sectional view illustrating attachment of the semiconductor device according to the first embodiment to a cooling device;

FIG. 5 is a side sectional view of a semiconductor device according to a second embodiment;

FIG. 6 is a plan view (a bottom surface) of a heat dissipation plate of the semiconductor device according to the second embodiment;

FIG. 7 is a side sectional view illustrating attachment of the semiconductor device according to the second embodiment to a cooling device;

FIG. 8 is a plan view (a bottom surface) of a heat dissipation plate of a semiconductor device according to the second embodiment (modification 2-1);

FIG. 9 is a side sectional view of a semiconductor device according to a third embodiment;

FIG. 10 is a table illustrating changes of a gap and stress between the first to third embodiments and the reference example;

FIG. 11 is a plan view (a top surface) of a heat dissipation plate of a semiconductor device according to a fourth embodiment;

FIG. 12 is a first side sectional view of the semiconductor device according to the fourth embodiment;

FIG. 13 is a second side sectional view of the semiconductor device according to the fourth embodiment;

FIG. 14 is a plan view (a bottom surface) of a heat dissipation plate of a semiconductor device according to a fifth embodiment; and

FIG. 15 is a plan view (a bottom surface) of a heat dissipation plate of a semiconductor device according to the fifth embodiment (modification 5-1).

### DETAILED DESCRIPTION OF THE INVENTION

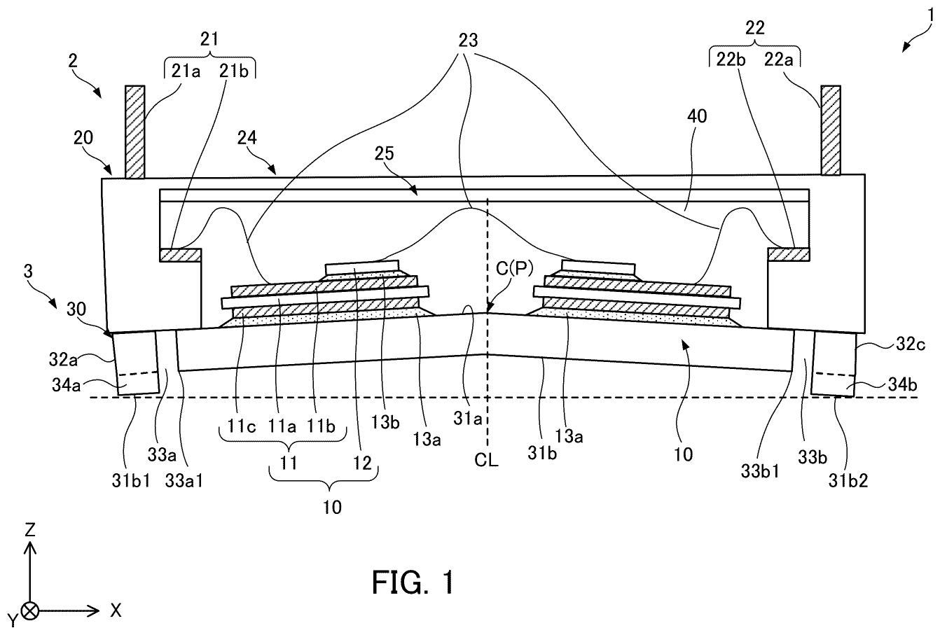

Hereinafter, embodiments will be described with reference to the accompanying drawings. In the following description, regarding a semiconductor device 1 in FIG. 1, terms “front surface” and “top surface” each express an X-Y surface facing upward (+Z direction). Likewise, regarding the semiconductor device 1 in FIG. 1, a term “up” expresses the upward direction (+Z direction). Regarding the semiconductor device 1 in FIG. 1, terms “rear surface” and “bottom surface” each express an X-Y surface facing downward (−Z direction). Likewise, regarding the semiconductor device 1 in FIG. 1, a term “down” expresses the downward direction (−Z direction). As needed, the above terms also mean their respective directions in the other drawings. The terms “front surface”, “top surface”, “up”, “rear surface”, “bottom surface”, “down”, and “side surface” are simply used as convenient expressions to determine relative positional relationships, and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material. In addition, in the drawings, description of the same components may be omitted or simplified, as needed. A component that has already been denoted by a reference character in one drawing may be illustrated without the reference character in other drawings, as needed. In this case, the reference character of the component is found in the one drawing.

### First Embodiment

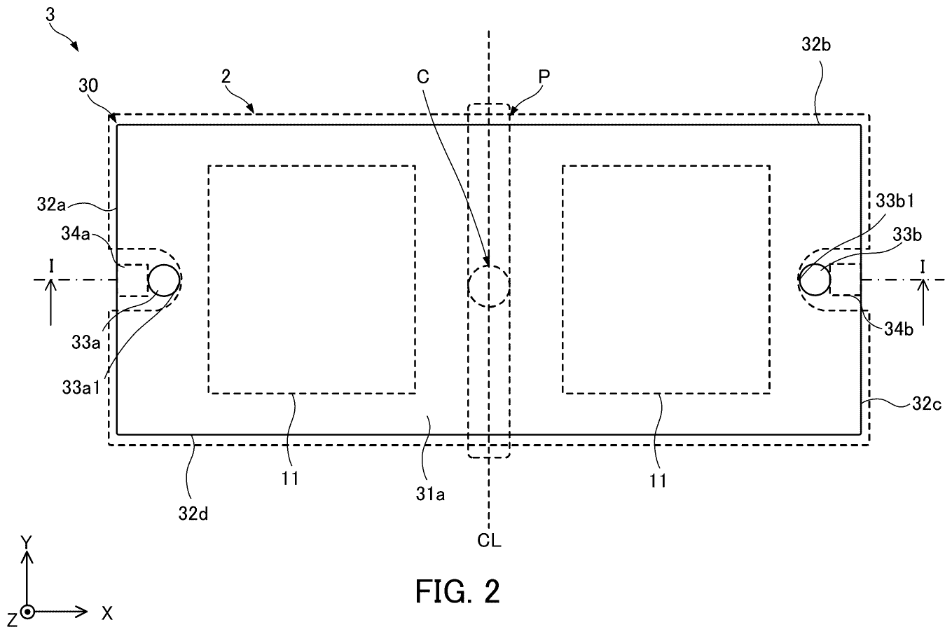

A semiconductor device 1 according to a first embodiment will be described with reference to FIGS. 1 and 2. FIG. 1 is a side sectional view of a semiconductor device according to a first embodiment. FIG. 2 is a plan view (a top surface) of a heat dissipation plate of the semiconductor device according to the first embodiment. Specifically, FIG. 2 illustrates a top surface 31a of a heat dissipation plate 3 included in the semiconductor device 1. In FIG. 2, insulated circuit boards 11 on the top surface 31a are indicated by dashed lines. When viewed from the top surface 31a, the locations of protrusions 34a and 34b on a bottom surface 31b are also indicated by dashed lines. Although a case 2 is not illustrated in FIG. 2, the location where the case 2 is disposed is also indicated by a dashed line. FIG. 1 is a sectional view taken along a dashed-dotted line I-I in FIG. 2.

The semiconductor device 1 the heat dissipation plate 3, two semiconductor units 10 that are bonded to the top surface 31a of the heat dissipation plate 3, and the case 2 that is disposed on the top surface 31a of the heat dissipation plate 3 and that covers the semiconductor units 10. The semiconductor units 10 in the case 2 are sealed by a sealing member 40.

The heat dissipation plate 3 includes a plate-shaped plate member 30 and the protrusions 34a and 34b. The plate member 30 has a flat plate shape (a plate shape), and has the rectangular top surface 31a and the bottom surface 31b, which has the same shape as the top surface 31a and is opposite to the top surface 31a. The top surface 31a and the bottom surface 31b may be a substantially flat surface. The plate member 30 has side surfaces 32a, 32b, 32c, and 32d, which sequentially surround the four sides of the top surface 31a and the bottom surface 31b. These side surfaces 32a, 32b, 32c, and 32d may also be a substantially flat surface. The plate member 30 may have one or more slopes or cutout portions. That is, the percentage of the one or more slopes or cutout portions in the longitudinal or lateral direction in plan view is small with respect to the entire plate member 30 (for example, less than 1%), and thus, the plate member 30 is considered as a substantially flat plate.

The side surfaces 32b and 32d extend in the longitudinal direction and connect to the top surface 31a at a pair of opposite first edges extending in the longitudinal direction of the top surface 31a. Similarly, the side surfaces 32b and 32d connect to the bottom surface 31b at a pair of opposite edges extending in the longitudinal direction of the bottom surface 31b. The side surfaces 32a and 32c extend in the lateral direction and connect to the top surface 31a at a pair of opposite second edges extending in the lateral direction of the top surface 31a. Similarly, the side surfaces 32a and 32c connect to the bottom surface 31b at a pair of opposite edges extending in the lateral direction of the bottom surface 31b. That is, in FIG. 2, the pair of first edges corresponds to the side surfaces 32b and 32d, and the pair of second edges corresponds to the side surfaces 32a and 32c.

In addition, the corner portions, the pair of first edges, and the pair of second edges of the plate member 30 may be rounded or chamfered. In plan view, a center line CL parallel to the side surfaces 32a and 32c is set for the plate member 30. A center portion C is set in the middle of the center line CL.

The plate member 30 has fastening holes 33a and 33b. The fastening holes 33a and 33b vertically extend through the top surface 31a and the bottom surface 31b. The fastening holes 33a and 33b formed in the plate member 30 have a cylindrical shape. The fastening holes 33a and 33b are formed in a peripheral area near the side surfaces 32a and 32c of the plate member 30. That is, in plan view, the fastening hole 33a is formed near the center of the side surface 32a (a second edge) of the plate member 30, and is located away from the side surface 32a (the second edge) by a predetermined distance in the inner direction (in the direction of the center line CL). Similarly, in plan view, the fastening hole 33b is formed near the center of the side surface 32c (a second edge) of the plate member 30, and is located away from the side surface 32c (the second edge) by a predetermined distance in the inner direction (in the direction of the center line CL). The fastening holes 33a and 33b may have a circular shape in plan view. In this case, the diameter of the fastening holes 33a and 33b may be selected based on the diameter of the screws to be used.

As viewed in any one of the +Y directions, the plate member 30 has been warped into a convex shape facing upward such that the center line CL is located above. That is, at least on the bottom surface 31b of the plate member 30, the center line CL including the center portion C protrudes upward, and there are downward slopes from the center line CL to end portions (the side surfaces 32a and 32c (a pair of second edges)). The center line CL of the plate member 30 protrudes to create a protruding portion P, and there are downward slopes from the protruding portion P to the side surfaces 32a and 32c (the pair of second edges). The angle of the slope from the protruding portion P on the top surface 31a to the side surface 32a may be somewhat different from the angle of the slope from the protruding portion P on the top surface 31a to the side surface 32c. Although the protruding portion P in FIG. 2 is located in an area including the center line CL, the protruding portion P may be located in an area other than the area indicated by the dashed line illustrated in FIG. 2.

The first embodiment is also applicable to a case in which the plate member 30 has been warped into a convex shape facing upward such that the center portion C is located above when viewed from any one of the ±X directions. However, in the first embodiment, the warp at the protruding portion P (when viewed from any one of the ±Y directions) is sufficiently large, and the warp at the center portion C when viewed from any one of the ±X directions is substantially ignorable.

The semiconductor units 10 (the insulated circuit boards 11 included therein) are bonded to the sloping areas on the top surface 31a of the plate member 30. In this case, the semiconductor units 10 are bonded to their respective sloping areas, which are equally distanced from the protruding portion P on the top surface 31a of the plate member 30 and each of which is located between the protruding portion P and a corresponding one of the fastening holes 33a and 33b. The semiconductor units 10 will be described in detail below.

The protrusion 34a is formed between the fastening hole 33a in the bottom surface 31b of the plate member 30 and the side surface 32a located in the opposite direction from the center portion C. Similarly, the protrusion 34b is formed between the fastening hole 33b in the bottom surface 31b of the plate member 30 and the side surface 32c located in the opposite direction from the center portion C. That is, the protrusion 34a is formed on a straight line connecting the center of the protrusion 34a, the center of the fastening hole 33a, and the center portion C. In addition, the protrusion 34b is formed on a straight line connecting the center of the protrusion 34b, the center of the fastening hole 33b, and the center portion C. In addition, the protrusion 34a may be formed anywhere between the side surface 32a and the fastening hole 33a, and the protrusion 34b may be formed anywhere between the side surface 32c and the fastening hole 33b. The protrusions 34a and 34b may be formed integrally with the bottom surface 31b of the plate member 30. The bottom surface of the protrusion 34a includes a peripheral portion 31b1, and the bottom surface of the protrusion 34b includes a peripheral portion 31b2. In other words, the peripheral portions 31b1 and 31b2, which are located on the bottom surface 31b of the plate member 30 in areas between the fastening hole 33a and the side surface 32a, and between the fastening hole 33b and the side surface 32c, respectively, are positioned near and on the respective opposite sides of the fastening holes 33a and 33b from the center portion C. These peripheral portions 31b1 and 31b2 are at the respective bottoms of the protrusions 34a and 34b, which are positioned lower than the bottom surface 31b at respective inner portions 33a1, 33b1 of the opening edges of the fastening holes 33a, 33b, which lie on the straight lines connecting the center of the fastening holes 33a, 33b and the center portion C.

The protrusions 34a and 34b may have a columnar shape. Examples of the columnar shape include a cylindrical shape and a prismatic shape. In FIG. 2, the protrusions 34a and 34b have a prismatic shape, and the peripheral portions 31b1 and 31b2 have a rectangular shape in plan view. The length of the ±Y direction width of the peripheral portions 31b1 and 31b2 may range from about the diameter of the fastening holes 33a and 33b to the length of the side surfaces 32b and 32d. FIG. 2 illustrates a case in which one side of each of the peripheral portions 31b1 and 31b2 is about the diameter of the fastening holes 33a and 33b. As illustrated in FIG. 2, the maximum length of the ±X direction width of the peripheral portion 31b1 in plan view is from the side surface 32a to the fastening hole 33a. Similarly, the maximum length of the ±X direction width of the peripheral portion 31b2 in plan view is from the side surface 32c to the fastening hole 33b. These protrusions 34a and 34b may be formed by performing die machining or mechanical processing on the bottom surface 31b of the plate member 30, for example.

The heat dissipation plate 3 described above is made of a metal material having an excellent heat dissipation. The metal material is, for example, copper, aluminum, or an alloy containing at least one of these kinds of elements. The surface of the heat dissipation plate 3 may be plated, so as to improve its corrosion resistance. Examples of the material used for this plating include nickel, a nickel-phosphorus alloy, and a nickel-boron alloy.

The individual semiconductor unit 10 includes an insulated circuit board 11 and a semiconductor chip 12. The insulated circuit board 11 includes an insulating plate 11a, a conductive circuit pattern 11b formed on the top surface of the insulating plate 11a, and a metal plate 11c formed on the bottom surface of the insulating plate 11a.

The insulating plate 11a has a rectangular shape in plan view. The insulating plate 11a may have rounded or chamfered corners. The insulating plate 11a is made of a ceramic material having a high thermal conductivity. This ceramic material contains, for example, aluminum oxide, silicon nitride, or aluminum nitride as its main component.

The insulating plate 11a may be made of a resin material. This resin material may be a material having a low thermal resistance and a high insulating property. For example, the resin material may be a thermosetting resin. Examples of the thermosetting resin include at least one of epoxy resin, cyanate resin, polyimide resin, benzoxazine resin, unsaturated polyester resin, phenolic resin, melamine resin, silicone resin, maleimide resin, acrylic resin, and polyamide resin.

The conductive circuit pattern 11b is made of a metal material having an excellent electrical conductivity. The metal material is, for example, copper, aluminum, or an alloy containing at least one of these kinds of elements. The surface of the circuit pattern may be plated, so as to improve the its corrosion resistance. Examples of the material used for this plating include nickel, a nickel-phosphorus alloy, and a nickel-boron alloy. The conductive circuit pattern 11b may have any shape that realizes a desired circuit. A plurality of conductive circuit patterns 11b may be formed.

The metal plate 11c is made of a material containing a metal material having an excellent thermal conductivity as its main component. The metal material is, for example, copper, aluminum, or an alloy containing at least one of these kinds of elements. The metal plate 11c may be plated, so as to improve its corrosion resistance. Examples of the material used for this plating include nickel, a nickel-phosphorus alloy, and a nickel-boron alloy.

If the insulating plate 11a of the insulated circuit board 11 is made of a ceramic material, a direct copper bonding (DCB) board or an active metal brazed (AMB) board may be used, for example.

For example, the semiconductor chip 12 may be made of silicon carbide, silicon, or gallium nitride as its main component. For example, the semiconductor chip 12 may be a power metal-oxide-semiconductor field-effect transistor (MOSFET) made of silicon carbide as its main component. The body diode of the power MOSFET may function as a freewheeling diode (FWD). In this case, the semiconductor chip 12 includes an input electrode (a drain electrode) as a main electrode on its rear surface, and includes an output electrode (a source electrode) as a main electrode and a control electrode (a gate electrode) on its front surface. The control electrode may be formed on the center of one side portion on the front surface of the semiconductor chip 12 or may be formed away from the center along the one side portion on the front surface of the semiconductor chip 12.

The semiconductor chip 12 may include a switching element made of silicon as its main component. The switching element may be a reverse-conducting (RC)-insulated gate bipolar transistor (IGBT), for example. The RC-IGBT is a semiconductor element constituted by forming an IGBT and an FWD in antiparallel in one chip. This semiconductor chip 12 includes an input electrode (a collector electrode) as a main electrode on its rear surface, and includes an output electrode (an emitter electrode) as a main electrode and a control electrode (a gate electrode) on its front surface. As is the case with the power MOSFET, the control electrode may be formed on the center of one side portion on the front surface of the semiconductor chip 12 or may be formed away from the center along the one side portion on the front surface of the semiconductor chip 12.

Alternatively, the semiconductor chip 12 may be semiconductor chips made of silicon as its main component and including a switching element and a diode element. Specifically, one semiconductor chip may be a switching element, and the other semiconductor chip may be a diode element. The switching element is, for example, a power MOSFET or IGBT. The semiconductor chip including the switching element includes, for example, an input electrode as a main electrode on its rear surface (a drain electrode in the case of a power MOSFET and a collector electrode in the case of an IGBT), and includes a gate electrode as a control electrode and an output electrode as a main electrode on its front surface (a source electrode in the case of a power MOSFET and an emitter electrode in the case of an IGBT). In addition, regarding the diode element, for example, a Schottky barrier diode (SBD) or a P-intrinsic-N (PIN) diode is used as an FWD. The semiconductor chip including the diode element includes an output electrode (a cathode electrode) as a main electrode on its rear surface, and includes an input electrode (an anode electrode) as a main electrode on its front surface.

The semiconductor unit 10 is constructed by bonding the bottom surface of the semiconductor chip 12 to the conductive circuit pattern 11b of the insulated circuit In addition, the metal board 11 via a bonding member 13b. plate 11c of the insulated circuit board 11 of the semiconductor unit 10 is bonded to the top surface 31a of the heat dissipation plate 3 via a bonding member 13a.

The bonding members 13a and 13b may be made of the same material. For example, solder is used as the bonding members 13a and 13b. Lead-free solder is used as the solder. The lead-free solder contains, for example, at least one of a tin-silver-copper alloy, a tin-zinc-bismuth alloy, a tin-copper alloy, and a tin-silver-indium-bismuth alloy as its main component. The soler may contain an additive. The additive is, for example, nickel, germanium, cobalt, antimony, or silicon. Since the solder containing such additive has improved wettability, luster, and bonding strength, the reliability is improved. The bonding members 13a and 13b may be a sintered body. When the bonding is performed with a sintered body, the sintered material is powder of silver, iron, copper, aluminum, titanium, nickel, tungsten, or molybdenum, for example.

The case 2 includes a frame portion 20 and a cover portion 24 covering the upper portion of the frame portion 20. The outer shape of the frame portion 20 is a generally rectangular shape matching the outer shape of the heat dissipation plate 3 in plan view, and has a frame shape. However, in plan view, portions of the frame portion 20, the portions corresponding to the fastening holes 33a and 33b when the frame portion 20 is disposed on the heat dissipation plate 3, are inwardly recessed (in the direction of the center line CL). A storage region 25 extends through the center of the frame portion 20. The bottom surface of the frame portion 20 is bonded to a continuous ring-shaped peripheral area on the top surface 31a of the heat dissipation plate 3 (the plate member 30) via adhesive or the like (not illustrated).

In addition, the frame portion 20 integrally includes external connection terminals 21 and 22. The external connection terminal 21 includes an external end portion 21a and an internal end portion 21b. The external connection terminal 22 includes an external end portion 22a and an internal end portion 22b. The external end portions 21a and 22a extend upward from the top surface of the frame portion 20. The internal end portions 21b and 22b are formed in the storage region 25 of the frame portion 20. The cover portion 24 is integrally formed with the upper portion of the frame portion 20, and covers the opening of the frame portion 20.

The case 2 may be formed by integrally forming the frame portion 20 including the external connection terminals 21 and 22 and the cover portion 24 through insert molding by using a thermoplastic resin. Examples of this resin material include polyphenylene sulfide resin, polybutylene terephthalate resin, polybutylene succinate resin, polyamide resin, and acrylonitrile butadiene styrene resin.

In the case 2, wires 23 electrically connect the internal end portion 21b of the external connection terminal 21, one conductive circuit pattern 11b, electrodes on the front surface of the semiconductor chips 12, the other conductive circuit pattern 11b, and the internal end portion 22b of the external connection terminal 22, as appropriate. FIG. 1 illustrates only a connection example of the wires 23. The wires 23 are made of a material having an excellent electrical conductivity. The material is, for example, gold, silver, copper, aluminum, or an alloy containing at least one of these kinds of elements. For example, the internal end portions 21b and 22b of the external connection terminals 21 and 22 may be connected to the conductive circuit patterns 11b via lead frames, instead of wires 23.

The sealing member 40 fills the storage region 25 surrounded by the heat dissipation plate 3 and the frame portion 20 of the case 2. The insulated circuit boards 11, the semiconductor chips 12, and the wires 23 inside the storage region 25 are sealed by the sealing member 40. The sealing member 40 is insulating polymer gel. Preferably, the sealing member 40 contains silicone gel as its main component.

A cooling device is attached to the semiconductor device 1 (to the bottom surface 31b of the heat dissipation plate 3) via a bonding member. In this way, the heat dissipation of the semiconductor device 1 is improved. This cooling device may be made of, for example, aluminum, iron, silver, copper, or an alloy containing at least one of these kinds of elements having an excellent thermal conductivity. The cooling device may be a heatsink or a water-cooled cooling device, for example. The heatsink may have a plurality of fins. The semiconductor device 1 is disposed on the cooling surface of the cooling device via a bonding member, and screws are inserted into the fastening holes 33a and 33b in the heat dissipation plate 3. The semiconductor device 1 is consequently fastened to the cooling device with the screws.

The bonding member is, for example, a thermal interface material (TIM), which is a generic term for various kinds of materials, such as thermally conductive grease, elastomer sheet, room temperature vulcanization (RTV) rubber, gel, and phase-change material. In addition, the bonding member may contain filler, so as to improve its thermal conductivity. The filler is, for example, a highly insulating and highly thermally conductive inorganic material. The inorganic material contains, as the main component, at least one selected from the group consisting of aluminum oxide, aluminum nitride, silicon nitride, and boron nitride, for example.

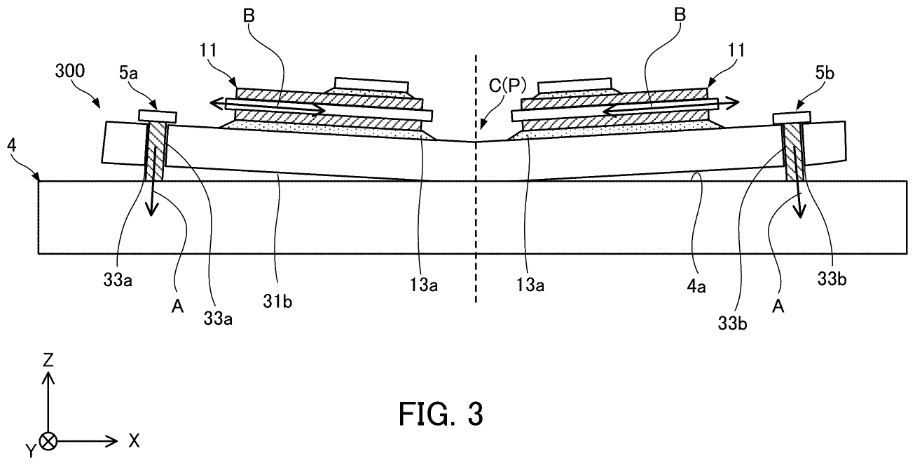

Next, a reference example, which will be compared with the semiconductor device 1, will be described with reference to FIG. 3. Herein, attachment of a semiconductor device according to the reference example to a cooling device will be described. FIG. 3 is a side sectional view illustrating attachment of a semiconductor device according to the reference example to a cooling device.

The semiconductor device according to the reference example has the same structure as that of the semiconductor device 1. However, unlike the heat dissipation plate 3 of the semiconductor device 1, a heat dissipation plate 300 included in the semiconductor device according to the reference example has been warped into a convex shape facing downward such that the center line CL is located below. In addition, the heat dissipation plate 300 according to the reference example does not include the protrusions 34a and 34b of the heat dissipation plate 3 according to the first embodiment. The case 2 is not illustrated in FIG. 3.

The bottom surface 31b of the heat dissipation plate 300 of the semiconductor device is disposed on a cooling surface 4a of a cooling device 4 via a bonding member such as TIM (not illustrated). Next, screws 5a and 5b are inserted into the fastening holes 33a and 33b, respectively, in the heat dissipation plate 300, and are screwed into the cooling surface 4a of the cooling device 4. In this step, stress is applied by the screws 5a and 5b in the directions indicated by arrows A illustrated in FIG. 3, and therefore, the heat dissipation plate 300 starts to deform to a flat shape as the center line CL on the bottom surface 31b functions as the fulcrum. The insulated circuit boards 11 are bonded to the heat dissipation plate 300, which has been warped into a convex shape facing downward, via their respective bonding members 13a. Thus, the insulated circuit boards 11 are pulled by the heat dissipation plate 300 deforming to a flat shape, and consequently, stress cleaving these insulated circuit boards 11 is also applied thereto in the directions indicated by arrows B illustrated in FIG. 3. If such stress indicated by the arrows B is applied to the insulated circuit boards 11 bonded on their respective slopes, the insulating plates 11a are damaged. For example, if a crack occurs and extends in the insulating plate 11a, the heat dissipation and the insulation of the insulated circuit boards 11 deteriorate. As a result, because the semiconductor chips 12 are not cooled and the insulation of the semiconductor chips 12 is not maintained, the semiconductor device consequently malfunctions.

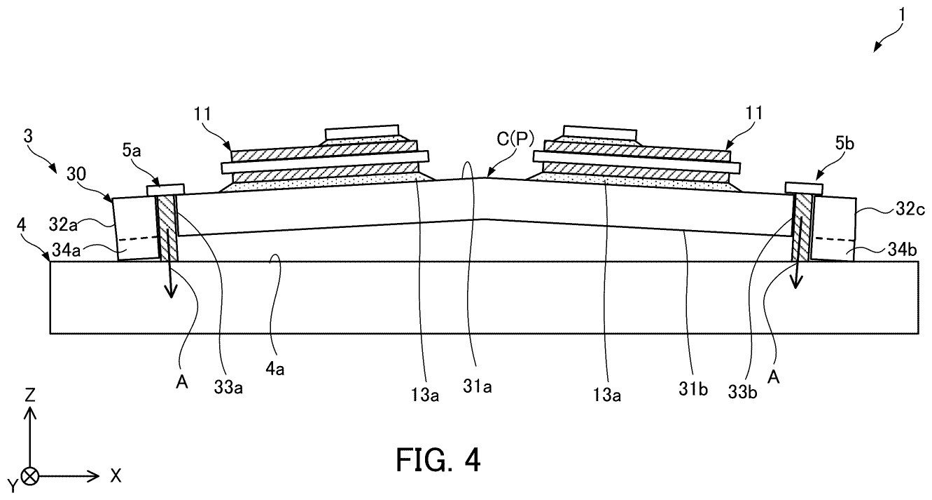

Next, attachment of the semiconductor device 1 to the cooling device 4 will be described with reference to FIG. 4. FIG. 4 is a side sectional view illustrating attachment of the semiconductor device according to the first embodiment to the cooling device. As in the reference example illustrated in FIG. 3, FIG. 4 illustrates a case in which the semiconductor device 1 is fastened to the cooling device 4 with the screws 5a and 5b. In addition, the case 2 of the semiconductor device 1 is not illustrated in FIG. 4.

In this case, as the screws 5a and 5b are screwed into the heat dissipation plate 3, stress is applied in the directions indicated by arrows A illustrated in FIG. 4. The heat dissipation plate 3 consequently starts to deform to a flat shape as the protrusions 34a and 34b function as the fulcrums. Because the heat dissipation plate 3 of the semiconductor device 1 has been warped into a convex shape facing upward, less stress is applied to the insulated circuit boards 11 in the directions indicated by the arrows B (see FIG. 3) than the stress applied according to the reference example. Thus, occurrence of the damage to the insulated circuit boards 11 is reduced.

Further screwing of the screws 5a and 5b into the cooling surface 4a applies greater stress to the heat dissipation plate 3 as the peripheral portions 31b1 and 31b2 (the reference characters are omitted in FIG. 4) of the protrusions 34a and 34b, the peripheral portions 31b1 and 31b2 being in contact with the cooling surface 4a, function as the fulcrums. As a result, the heat dissipation plate 3 is further flattened, and the bottom surface 31b approaches the cooling surface 4a. Thus, the gap between the bottom surface 31b of the heat dissipation plate 3 and the cooling surface 4a is reduced. If this gap is reduced, the thickness of the bonding member such as TIM is also reduced. As a result, the deterioration in heat dissipation is reduced. It is preferable that this gap be as small as possible. For example, the gap may be about the diameter of the filler included in the bonding member such as TIM.

The above-described semiconductor device 1 includes the insulated circuit board 11 and the heat dissipation plate 3. The heat dissipation plate 3 has a plate shape, and has the top surface 31a and the bottom surface 31b. At least the bottom surface 31b has the center portion C that protrudes upward, and the heat dissipation plate 3 has downward slopes from the center portion C to the side surfaces 32a and 32c (a pair of second edges). The top surface 31a has sloping areas on which the insulated circuit boards 11 are bonded, and the heat dissipation plate 3 has the fastening holes 33a and 33b that extend through the top surface 31a and the bottom surface 31b in its peripheral areas. In addition, the peripheral portions 31b1 and 31b2 provided near the fastening holes 33a and 33b in the bottom surface 31b of the heat dissipation plate 3 in the direction opposite to the center portion C protrudes downward. Even when the semiconductor device 1 is fastened to the cooling surface 4a of the cooling device 4 by inserting the screws 5a and 5b into the fastening holes 33a and 33b in the heat dissipation plate 3, less stress is applied to the insulated circuit boards 11. In addition, the gap between the bottom surface 31b of the heat dissipation plate 3 and the cooling surface 4a of the cooling device 4 is reduced. As a result, occurrence of damage to the insulated circuit boards 11 and deterioration in heat dissipation are reduced, whereby deterioration in reliability of the semiconductor device 1 is reduced.

### Second Embodiment

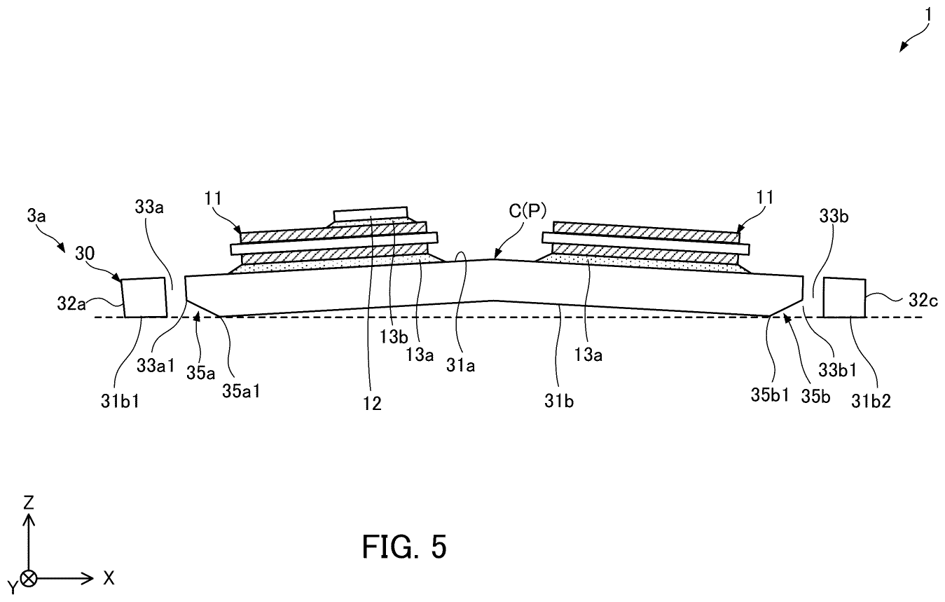

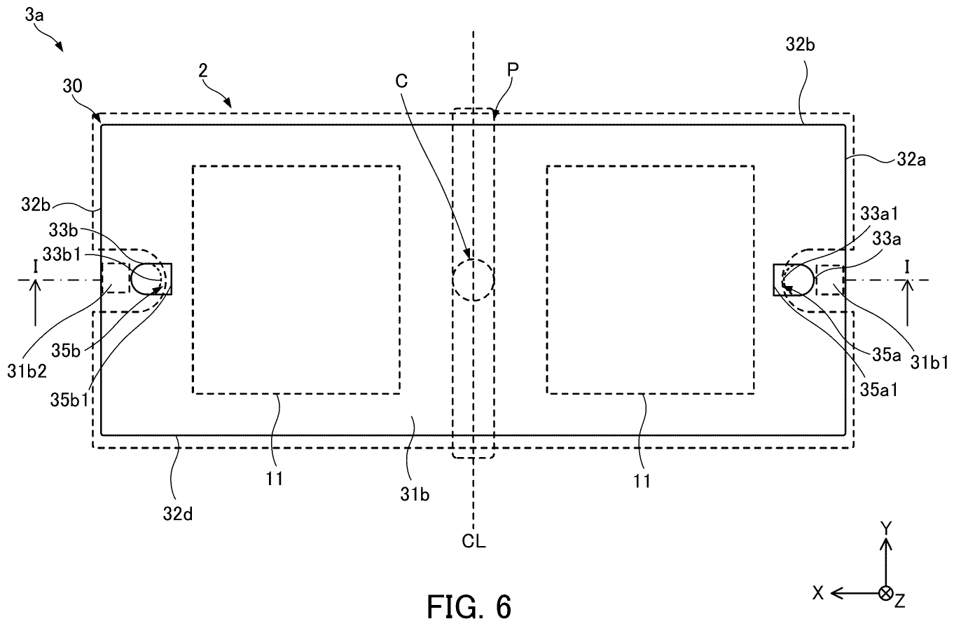

A heat dissipation plate according to a second embodiment will be described with reference to FIGS. 5 and 6. FIG. 5 is a side sectional view of a semiconductor device according to a second embodiment. FIG. 6 is a plan view (a bottom surface) of a heat dissipation plate of the semiconductor device according to the second embodiment. FIG. 5 corresponds to FIG. 1 without the case 2, and FIG. 6 illustrates the bottom surface of the heat dissipation plate 3a in FIG. 5. In addition, FIG. 5 is a sectional view taken along a dashed-dotted line I-I in FIG. 6. In the following side sectional views of the semiconductor devices 1 according to the second and subsequent embodiments, and in the following side sectional views illustrating attachment of each of these semiconductor devices 1 to a cooling device 4, their respective heat dissipation plates will be described without illustration of the case 2.

The semiconductor device according to the second embodiment has the same structure as that of the semiconductor device 1 according to the first embodiment, except for the heat dissipation plate 3. A heat dissipation plate 3a included in the semiconductor device according to the second embodiment includes a plate-shaped plate member 30 without protrusions.

The plate member 30 according to the second embodiment has the same structure as that of the plate member 30 according to the first embodiment, except for the fastening holes 33a and 33b. Thus, the peripheral portions 31b1 and 31b2 of the plate member 30 are on the same plane with the bottom surface 31b. The ±Y direction width of the peripheral portions 31b1 and 31b2 matches the ±Y direction width of cutout portions 35a and 35b, which will be described below.

The plate member 30 according to the second embodiment has the cutout portions 35a and 35b (recessed portions), each of which is located at an edge of an opening in the bottom surface 31b, the opening being part of a corresponding one of the fastening holes 33a and 33b and the edge facing in the direction of the center portion C. That is, in the case of the plate member 30 according to the second embodiment, the edges of the openings of the fastening holes 33a and 33b, the openings in the bottom surface 31b of the plate member 30 and the edges facing in the direction of the center portion C, are recessed, and inner portions 33a1 and 33b1 of the opening edges, the inner portions 33a1 and 33b1 being located in the direction of the center portion C, are located (recessed) above the bottom surface 31b (in the +Z direction). It is preferable that the height of the inner portions 33a1 and 33b1 from the bottom surface 31b be between 3% and 10%, inclusive, of the thickness of the plate member 30, for example.

The cutout portions 35a and 35b are formed in any way, as long as each of the cutout portions 35a and 35b includes part of an edge of an opening in the bottom surface 31b, the opening being part of a corresponding one of the fastening holes 33a and 33b and the edge facing in the direction of the center portion C. These cutout portions 35a and 35b may be formed from the side surface 32b to the side surface 32d of the plate member 30. In addition, in plan view, the cutout portions 35a and 35b including the inner portions 33a1 and 33b1 of the fastening holes 33a and 33b extend in a rectangular shape in the direction of the center portion C. The cutout portions 35a and 35b have edge portions 35a1 and 35b1, respectively, in the direction of the center portion C. These edge portions 35a1 and 35b1 may be located away from the inner portions 33a1 and 33b1 of the fastening holes 33a and 33b, respectively, in the direction of the center portion C. The edge portion 35a1 may be located between the inner portion 33a1 and a side of the corresponding insulated circuit board 11, the side being in the direction of the side surface 32a, in plan view. Similarly, the edge portion 35b1 may be located between the inner portion 33b1 and a side of the corresponding insulated circuit board 11, the side being in the direction of the side surface 32b, in plan view. If the edge portions 35a1 and 35b1 of the cutout portions 35a and 35b are located beyond the above-described sides of their respective insulated circuit boards 11, the sides being in the direction of their respective side surfaces 32a and 32b, in the direction of the center portion C, the edge portions 35a1 and 35b1 do not sufficiently function as the fulcrums when the semiconductor device 1 is fastened to the cooling device 4 with the screws 5a and 5b, as will be described below.

In addition, as illustrated in FIG. 5, when viewed from any one of the ±Y directions, the cutout portion 35a is recessed to linearly slope from the inner portion 33a1 of the fastening hole 33a to the edge portion 35a1, and the cutout portion 35b is recessed to linearly slope from the inner portion 33b1 of the fastening hole 33b to the edge portion 35b1. The cutout portions 35a and 35b may be formed in another way. For example, the cutout portions 35a and 35b may be recessed in an L shape, extending from the inner portions 33a1 and 33b1 to the edge portions 35a1 and 35b1, respectively. In this case, corner portions of the individual L shape may be rounded.

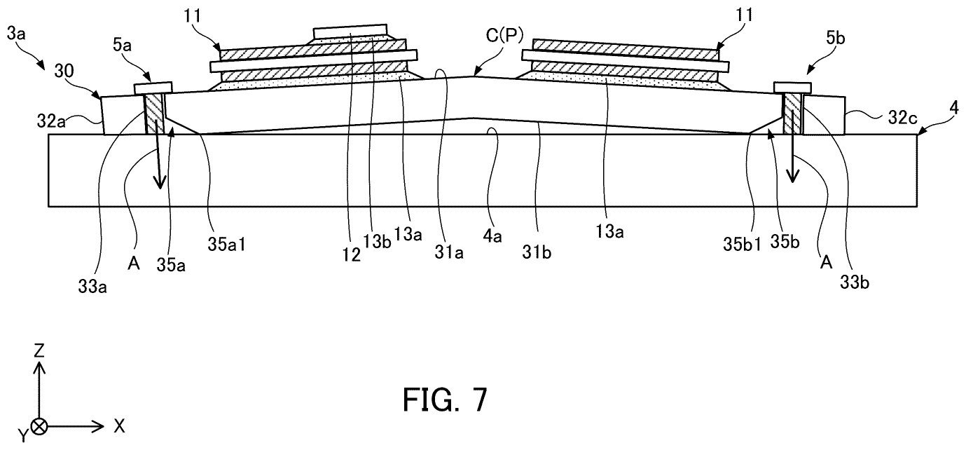

Next, attachment of the semiconductor device 1 (the heat dissipation plate 3a) according to the second embodiment to the cooling device 4 will be described with reference to FIG. 7. FIG. 7 is a side sectional view illustrating attachment of the semiconductor device according to the second embodiment to the cooling device. According to the second embodiment, as in the first embodiment, the semiconductor device 1 (the heat dissipation plate 3a) is fastened to the cooling surface 4a of the cooling device 4 with the screws 5a and 5b.

In this case, too, the screws 5a and 5b inserted into the fastening holes 33a and 33b in the semiconductor device 1 (the heat dissipation plate 3a) disposed on the cooling surface 4a of the cooling device 4 are screwed into the cooling surface 4a. In this process, as the heat dissipation plate 3a is flattened, the inner portions 33a1 and 33b1 of the fastening holes 33a and 33b come into contact with the cooling surface 4a.

Further screwing of the screws 5a and 5b applies stress in the directions indicated by arrows A illustrated in FIG. 7, and the bottom surface 31b of the center portion C of the heat dissipation plate 3a approaches the cooling surface 4a. In this case, too, as in the first embodiment, occurrence of damage to the insulated circuit boards 11 is reduced.

Further screwing of the screws 5a and 5b into the cooling surface 4a applies stress to the heat dissipation plate 3a as the edge portions 35a1 and 35b1 of the bottom surface 31b, the edge portions 35a1 and 35b1 being in contact with the cooling surface 4a, function as the fulcrums. As the heat dissipation plate 3a is flattened, the bottom surface 31b approaches the cooling surface 4a. Thus, as in the first embodiment, the gap between the bottom surface 31b of the heat dissipation plate 3a and the cooling surface 4a is reduced. If this gap is reduced, the thickness of the bonding member is also reduced. As a result, the deterioration in heat dissipation is also reduced.

In the case of the heat dissipation plate 3 according to the first embodiment, when the heat dissipation plate 3 is fastened to the cooling surface 4a with the screws 5a and 5b inserted into the fastening holes 33a and 33b, the bottom surface 31b of the heat dissipation plate 3 approaches the cooling surface 4a as the peripheral portions 31b1 and 31b2 of the protrusions 34a and 34b function as the fulcrums.

In the case of the heat dissipation plate 3a according to the second embodiment, the peripheral portions 31b1 and 31b2 are on the same plane with the bottom surface 31b, and the inner portion 33a1 and 33b1 of the opening edges of the fastening holes 33a and 33b are located above the peripheral portions 31b1 and 31b2. Thus, when the heat dissipation plate 3a is fastened to the cooling surface 4a with the screws 5a and 5b inserted into the fastening holes 33a and 33b, the bottom surface 31b of the heat dissipation plate 3a approaches the cooling surface 4a as the inner portions 33a1 and 33b1 on the bottom surface 31b of the heat dissipation plate 3a function as the fulcrums.

In the case of the heat dissipation plates 3 and 3a according to the first and second embodiments, the peripheral portions 31b1 and 31b2 on the bottom surface 31b of the heat dissipation plates 3 and 3a are located below (in the −Z direction) the inner portions 33a1 and 33b1 of the opening edges of the fastening holes 33a and 33b, the inner portions 33a1 and 33b1 being located in the direction of the center portion C. By fastening the heat dissipation plates 3 and 3a to the cooling surface 4a of cooling device 4 with the screws 5a and 5b inserted into the fastening holes 33a and 33b, it is possible to reduce the stress applied to the insulated circuit boards 11 bonded to the top surface 31a, and to reduce the gap between the bottom surface 31b and the cooling surface 4a.

### Modification 2-1 of Second Embodiment

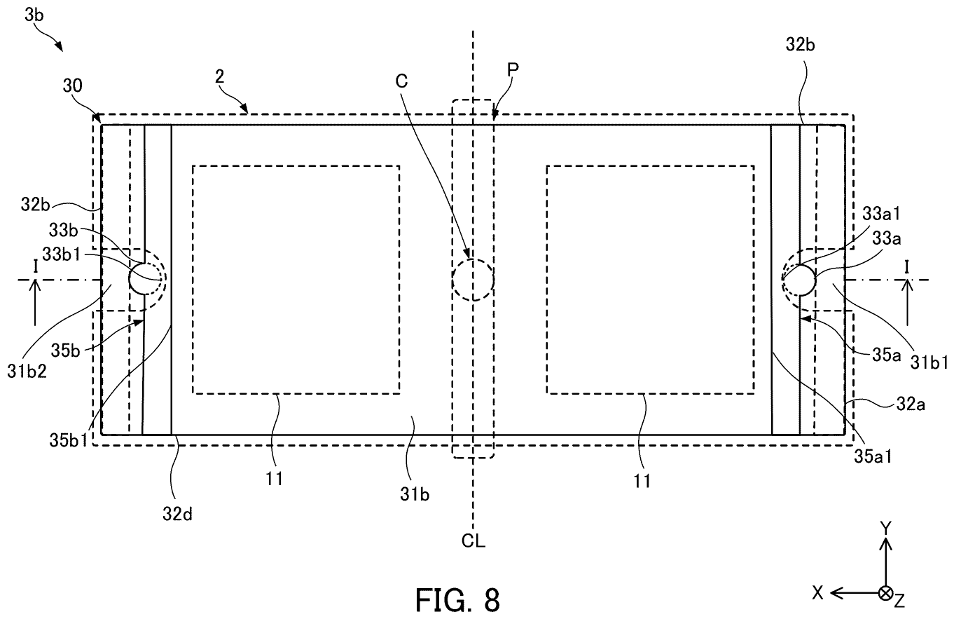

A heat dissipation plate 3b according to modification 2-1 includes cutout portions 35a and 35b different from those of the heat dissipation plate 3a according to the second embodiment. The heat dissipation plate 3b according to modification 2-1 will be described with reference to FIG. 8. FIG. 8 is a plan view (a bottom surface) of a heat dissipation plate of a semiconductor device according to the second embodiment (modification 2-1).

Except for the cutout portions 35a and 35b, the heat dissipation plate 3b has the same structure as that of the heat dissipation plate 3a according to the second embodiment. Edge portions 35a1 and 35b1 of the cutout portions 35a and 35b of the heat dissipation plate 3b extend longer in the direction of the side surfaces 32b and 32d than the edge portions 35a1 and 35b1 of the cutout portions 35a and 35b of the heat dissipation plate 3a. If the edge portions 35a1 and 35b1 of the heat dissipation plate 3b are too short, deformation of the heat dissipation plate 3b could be hindered. Thus, it is preferable that the edge portions 35a1 and 35b1 extend approximately to sides of the insulated circuit boards 11, the sides being located in the direction of the side surfaces 32b and 32d, for example. As is the case with the heat dissipation plate 3a, the edge portion 35a1 of the cutout portion 35a may be located between the inner portion 33a1 of the fastening hole 33a and the side of the insulated circuit board 11, the side being located in the direction of the side surface 32a. Similarly, the edge portion 35b1 of the cutout portion 35b may be located between the inner portion 33b1 of the fastening hole 33b and the side of the insulated circuit board 11, the side being located in the direction of the side surface 32b. The ±Y direction width of the peripheral portions 31b1 and 31b2 of the heat dissipation plate 3b is also set to be approximately equal to the ±Y direction width of the cutout portions 35a and 35b.

By widening the ±Y direction width of the edge portions 35a1 and 35b1 of the cutout portions 35a and 35b included in the heat dissipation plate 3b, the edge portions 35a1 and 35b1 come into contact with the cooling surface 4a in a wider area when the heat dissipation plate 3b is fastened to the cooling surface 4a with the screws 5a and 5b. As result, the heat dissipation plate 3b is stably supported.

By using the heat dissipation plate 3b as described above, as is the case with the heat dissipation plate 3a, the stress applied to the insulated circuit boards 11 bonded to the top surface 31a is reduced. In addition, the gap between the bottom surface 31b and the cooling surface 4a is reduced more securely, compared with the gap formed when the heat dissipation plate 3a is used.

In modification 2-1, the cutout portions 35a and 35b have a rectangular shape in plan view, and extend in the direction of the center portion C, including the inner portions 33a1 and 33b1 of the fastening holes 33a and 33b. The shape of the cutout portions 35a and 35b in plan view is not limited to the above-described shape. For example, the shape of the cutout portions 35a and 35b in plan view may be a triangular shape. In this case, the center point of each of the fastening holes 33a and 33b may be the vertex, and each of the edge portions 35a1 and 35b1 may face the corresponding vertex. Alternatively, the shape of each of the cutout portions 35a and 35b in plan view may be a trapezoidal shape. In this case, the diameter going through the center of each of the fastening holes 33a and 33b may be the upper base, and each of the edge portions 35a1 and 35b1 may be the lower base.

### Third Embodiment

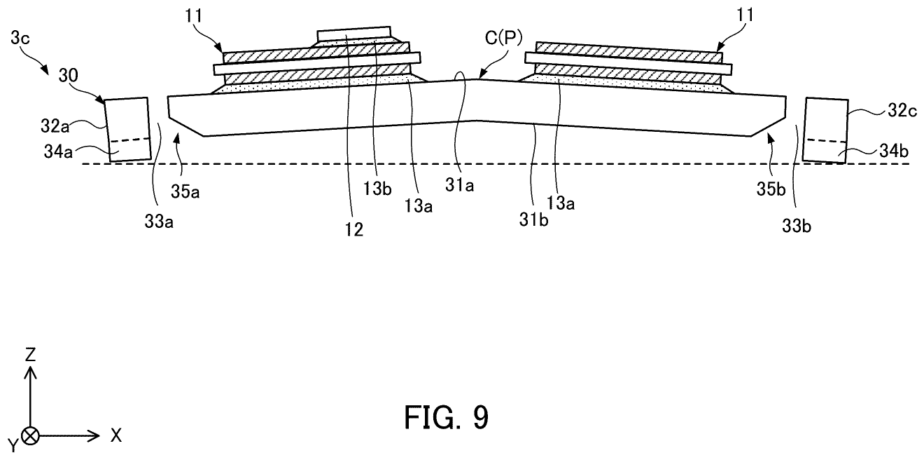

A heat dissipation plate according to a third embodiment has a bottom surface 31b having protrusions 34a and 34b as in the first embodiment, and has cutout portions 35a and 35b in the bottom surface 31b near their respective fastening holes 33a and 33b as in the second embodiment. A heat dissipation plate 3c as described above will be described with reference to FIG. 9. FIG. 9 is a side sectional view of a semiconductor device according to a third embodiment. The side sectional view according to the third embodiment illustrated in FIG. 9 corresponds to the side sectional views according to the first and second embodiments illustrated in FIGS. 1 and 5.

The heat dissipation plate 3c according to the third embodiment includes the cutout portions 35a and 35b, including the inner portions 33a1 and 33b1 at the opening edges of the fastening holes 33a and 33b in the bottom surface 31b of the heat dissipation plate 3 according to the first embodiment.

As in the first and second embodiments, the heat dissipation plate 3c is also fastened to the cooling surface 4a of the cooling device 4 with the screws 5a and 5b inserted into the fastening holes 33a and 33b. Use of the heat dissipation plate 3c reduces the stress applied to the insulated circuit boards 11 bonded to the top surface 31a, and also reduces the gap between the bottom surface 31b and the cooling surface 4a.

As in modification 2-1, by widening the edge portions 35a1 and 35b1 of the cutout portions 35a and 35b of the heat dissipation plate 3c, the edge portions 35a1 and 35b1 are able to support the heat dissipation plate 3c more stably.

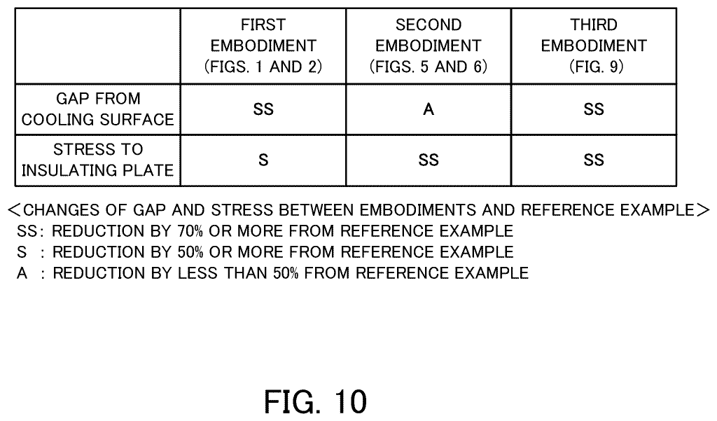

Hereinafter, how the gap between the bottom surface 31b and the cooling surface 4a and the stress applied to the insulated circuit boards 11 change between when the heat dissipation plate 300 according to the reference example is used and when the heat dissipation plates 3, 3a, and 3c according to the first, second, and third embodiments are used will be described with reference to FIG. 10. FIG. 10 is a table illustrating changes of the gap and stress between the first to third embodiments and the reference example. FIG. 10 illustrates how the gap between the bottom surface 31b and the cooling surface 4a and the stress applied to the insulated circuit boards 11 improve by using the heat dissipation plates 3, 3a, and 3c according to the first, second, and third embodiments, instead of using the heat dissipation plate 300 according to the reference example. In this table, “SS” indicates that the gap and the stress have been reduced (improved) by 70% or more from those obtained when the heat dissipation plate 300 according to the reference example is used. Similarly, “S” indicates reduction by 50% or more, and “A” indicates reduction by less than 50%.

Use of the heat dissipation plate 3 according to the first embodiment achieves reduction of the gap between the bottom surface 31b and the cooling surface 4a by 70% or more from the gap formed when the heat dissipation plate 300 according to the reference example is used. The stress applied to the insulated circuit boards 11 is reduced by 50% or more.

Use of the heat dissipation plate 3a according to the second embodiment achieves reduction of the gap between the bottom surface 31b and the cooling surface 4a by less than 50% from the gap formed when the heat dissipation plate 300 according to the reference example is used. In addition, the stress applied to the insulated circuit boards 11 is reduced by 70% or more.

In addition, use of the heat dissipation plate 3c according to the third embodiment achieves improvement of the gap between the bottom surface 31b and the cooling surface 4a and the stress applied to the insulated circuit boards 11 by 70% or more from the gap and the stress obtained when the heat dissipation plate 300 according to the reference example is used.

Considering this result, any one of the heat dissipation plates 3, 3a, and 3c according to the first, second, and third embodiments achieves improvement of the gap and stress from those of the heat dissipation plate 300 according to the reference example. In particular, use of the heat dissipation plate 3c according to the third embodiment achieves greater improvement.

### Fourth Embodiment

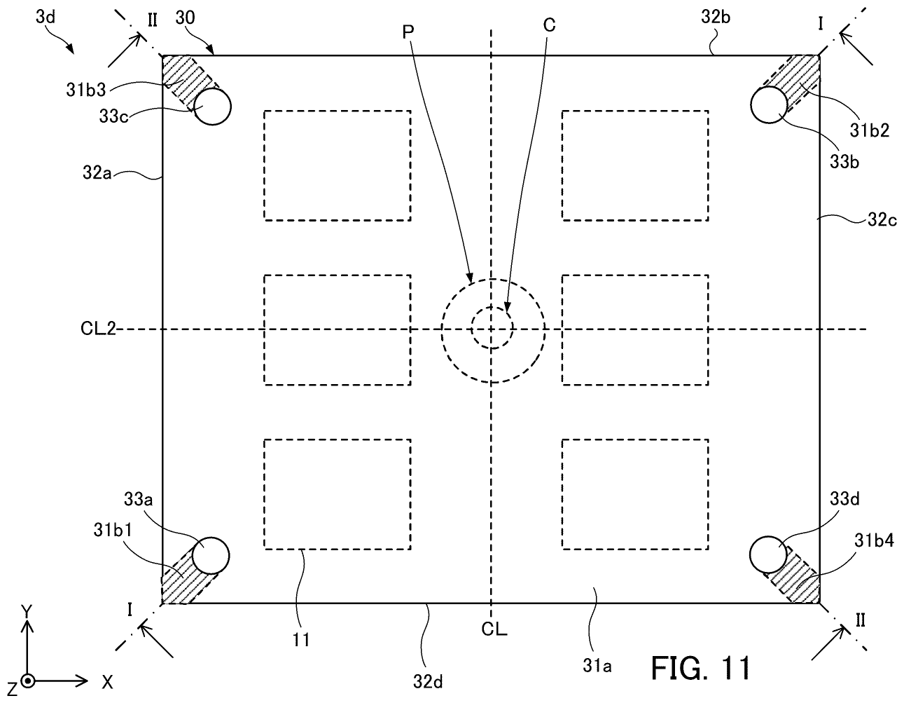

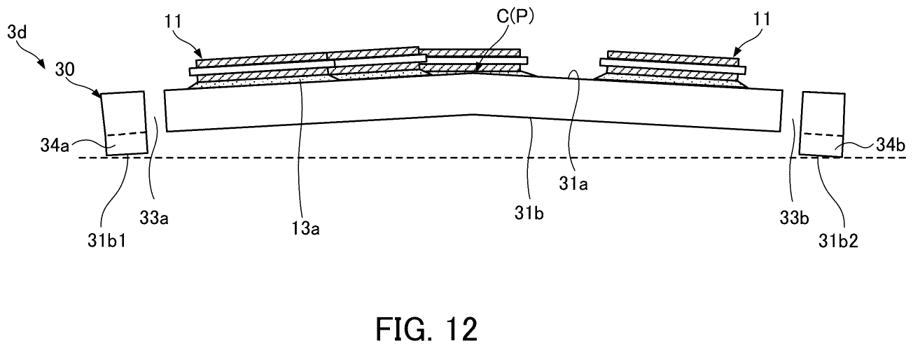

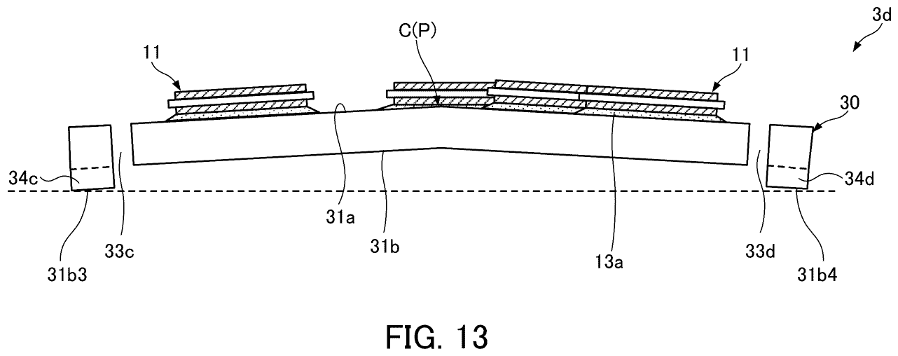

A heat dissipation plate included in a semiconductor device according to a fourth embodiment has longer side surfaces 32a and 32c in the ±Y directions than those of the heat dissipation plate according to the first, second, and third embodiments, and has fastening holes in four corners. A heat dissipation plate 3d according to the fourth embodiment will be described with reference to FIGS. 11 to 13. FIG. 11 is a plan view (a top surface) of a heat dissipation plate of a semiconductor device according to a fourth embodiment. FIG. 12 is a first side sectional view of the semiconductor device according to the fourth embodiment. FIG. 13 is a second side sectional view of the semiconductor device according to the fourth embodiment. In FIGS. 11 to 13, the case is not illustrated. In FIG. 11, the insulated circuit boards 11 are indicted by dashed lines. Three insulated circuit boards 11 are disposed on each of the right and left sides of the center line CL. The number of insulated circuit boards 11 is an example. In addition, protrusions are formed on the bottom surface 31b, and the locations of these protrusions are hatched on the top surface 31a. FIG. 12 is a sectional view taken along a dashed-dotted line I-I in FIG. 11, and FIG. 13 is a sectional view taken along a dashed-dotted line II-II in FIG. 11.

The semiconductor units 10 (the insulated circuit boards 11) and the bonding members 13a and 13b of the semiconductor device according to the fourth embodiment are the same as those according to the first embodiment. The case may be constructed based on the number of and the arrangement of these semiconductor units 10.

The heat dissipation plate 3d according to the fourth embodiment includes a plate-shaped plate member 30 and protrusions 34a, 34b, 34c, and 34d. The plate member 30 has longer side surfaces 32a and 32c extending in the lateral direction than those according to the first embodiment. A center line CL parallel to the side surfaces 32a and 32c in plan view is set for the plate member 30, and a center line CL2 perpendicular to the center line CL and parallel to side surfaces 32b and 32d is set for the plate member 30. An area including the intersection of the center lines CL and CL2 is a center portion C.

The plate member 30 has fastening holes 33a, 33b, 33c, and 33d. Each of the fastening holes 33a, 33b, 33c, and 33d is formed in a corner portion where one of the side surfaces 32b and 32d (a pair of first edges) meets one of the side surfaces 32a and 32c (a pair of second edges). Specifically, the fastening hole 33a is formed in a corner portion located where the side surfaces 32d and 32a meet, and the fastening hole 33b is formed in a corner portion located where the side surfaces 32b and 32c meet. The fastening hole 33c is formed in a corner portion located where the side surfaces 32a and 32b meet, and the fastening hole 33d is formed in a corner portion located where the side surfaces 32c and 32d meet. The fastening holes 33a, 33b, 33c, and 33d vertically extend through the top surface 31a and the bottom surface 31b. The fastening holes 33a, 33b, 33c, and 33d formed in the plate member 30 have a cylindrical shape. Each of the fastening holes 33a, 33b, 33c, and 33d is formed in a peripheral area of the plate member 30. In addition, the fastening holes 33a and 33b are formed on a diagonal line going through the corner portions in which the fastening holes 33a and 33b are formed and through the center portion C. The fastening holes 33c and 33d are formed on a diagonal line going through the corner portions in which the fastening holes 33c and 33d are formed and through the center portion C. The fastening holes 33a, 33b, 33c, and 33d are formed away from their respective corner portions of the plate member 30 by a predetermined distance in the direction of the center portion C along their respective diagonal lines. Each of the fastening holes 33a, 33b, 33c, and 33d may also have a circular shape in plan view. In this case, the diameter of the fastening holes 33a, 33b, 33c, and 33d may be selected based on the diameter of the screws to be used.

In addition, as viewed in any one of the ±Y directions and the ±X directions, the plate member 30 has been warped into a convex shape facing upward such that the center portion C is located above. That is, at least on the bottom surface 31b of the plate member 30, the center portion C protrudes upward, and there are downward slopes, each of which extends from the center portion C to a corresponding one of the end portions (the side surfaces 32a and 32c (a pair of second edges) and the side surfaces 32b and 32d (a pair of first edges)). A protruding portion P is formed at the center portion C of the plate member 30, and there are downward slopes, each of which extends from the protruding portion P to a corresponding one of the side surfaces 32a and 32c (the pair of second edges) and the side surfaces 32b and 32d (the pair of first edges). The protruding portion P in FIG. 11 is formed in an area including the center portion C.

The semiconductor units 10 (the insulated circuit boards 11 included therein) are bonded to their respective sloping areas on the top surface 31a of the plate member 30 via the bonding members 13a. In this case, the semiconductor units 10 on the right side and the semiconductor units 10 on the left side are equally distanced from the protruding portion P on the top surface 31a of the plate member 30. Specifically, the semiconductor units 10 are disposed in two columns on the right and left sides of the center line CL on the top surface 31a, and the three semiconductor units 10 on each side are bonded at regular intervals.

The protrusions 34a, 34b, 34c, and 34d are formed between the fastening holes 33a, 33b, 33c, and 33d in the bottom surface 31b of the plate member 30 and their respective corner portions located in the direction opposite to the center portion C (within the hatched areas in FIG. 11). These hatched areas are peripheral portions 31b1, 31b2, 31b3, and 31b4. For example, the peripheral portion 31b1 ranges from the fastening hole 33a to the side surfaces 32d and 32a located in the direction opposite to the center portion C. The peripheral portions 31b2, 31b3, and 31b4 also range from the fastening holes 33b, 33c, and 33d to their respective side surfaces.

The protrusions 34a, 34b, 34c, and 34d may be formed integrally with the bottom surface 31b of the plate member 30. The protrusions 34a, 34b, 34c, and 34d includes the peripheral portions 31b1, 31b2, 31b3, and 31b4 on their respective bottom surfaces. In other words, the peripheral portions 31b1, 31b2, 31b3, and 31b4 located in the direction opposite the center portion C and near the fastening holes 33a, 33b, 33c, and 33d in the bottom surface 31b of the plate member 30 protrude downward.

The protrusions 34a, 34b, 34c, and 34d may have a columnar shape. Examples of the columnar shape include a cylindrical shape and a prismatic shape. The protrusions 34a, 34b, 34c, and 34d may have a shape as illustrated by the hatching in FIG. 11. Alternatively, the columnar protrusions 34a, 34b, 34c, and 34d may be formed within their respective areas in FIG. 11. In this case, the width of the peripheral portions 31b1, 31b2, 31b3, and 31b4, the width facing the center portion C, may be approximately the diameter of the fastening holes 33a, 33b, 33c, and 33d.

The heat dissipation plate 3d is also made of a metal material having an excellent heat dissipation, as is the case with the heat dissipation plate 3 according to the first embodiment. In addition, the surface of the heat dissipation plate 3d may be plated, as in the first embodiment.

The stress applied to the insulated circuit boards 11 is also reduced by fastening the heat dissipation plate 3d of the semiconductor device to the cooling surface 4a of the cooling device 4 (not illustrated) after inserting screws (not illustrated) into the fastening holes 33a, 33b, 33c, and 33d. In addition, the heat dissipation plate 3d achieves reduction of the gap between the bottom surface 31b of the heat dissipation plate 3d and the cooling surface 4a of the cooling device 4 as the protrusions 34a, 34b, 34c, and 34d function as the fulcrums. As a result, occurrence of damage to the insulated circuit boards 11 and deterioration in heat dissipation are reduced. Consequently, deterioration in reliability of the semiconductor device is reduced.

### Fifth Embodiment

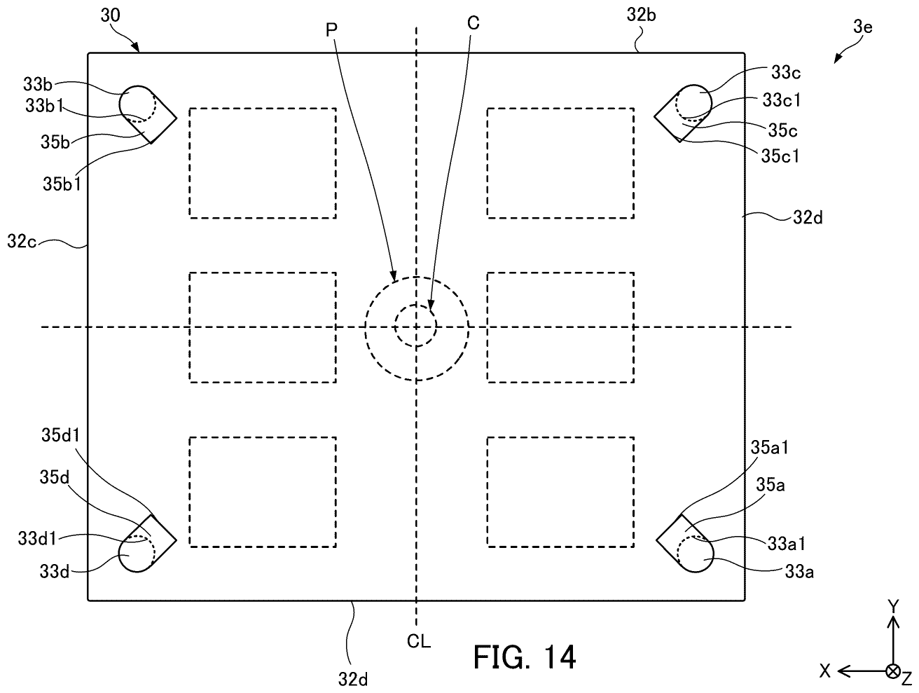

A heat dissipation plate according to a fifth embodiment does not have the protrusions 34a, 34b, 34c, and 34d of the heat dissipation plate 3d according to the fourth embodiment, but has cutout portions as in the second embodiment. A heat dissipation plate 3e according to a fifth embodiment will be described with reference to FIG. 14. FIG. 14 is a plan view (a bottom surface) of a heat dissipation plate of a semiconductor device according to a fifth embodiment.

The heat dissipation plate 3e included in the semiconductor device according to the fifth embodiment includes a plate-shaped plate member 30 without a protrusion. This plate member 30 has the same structure as the plate member 30 according to the fourth embodiment, except for the fastening holes 33a, 33b, 33c, and 33d. Thus, the peripheral portions 31b1, 31b2, 31b3, and 31b4 of the plate member 30 are on the same plane with the bottom surface 31b. In FIG. 14 according to the fifth embodiment, the peripheral portions 31b1, 31b2, 31b3, and 31b4 are not illustrated.

The plate member 30 according to the fifth embodiment includes cutout portions 35a, 35b, 35c, and 35d at opening edges of the fastening holes 33a, 33b, 33c, and 33d in the bottom surface 31b, the opening edges facing the center portion C. That is, in the case of the plate member 30 according to the fifth embodiment, unlike the bottom surface 31b of the plate member 30 according to the fourth embodiment, the opening edges of the fastening holes 33a, 33b, 33c, and 33d, the opening edges facing the center portion C, are recessed. In addition, the inner portions 33a1, 33b1, 33c1, and 33d1 of the opening edges, the inner portions 33a1, 33b1, 33c1, and 33d1 facing the center portion C, are located above the bottom surface 31b (in the +Z direction). Each of the cutout portions 35a, 35b, 35c, and 35d is formed in the same way as the cutout portions 35a and 35b according to the second embodiment, and is formed suitably based on the shape of the plate member 30 according to the fifth embodiment.

The heat dissipation plate 3e included in the semiconductor device is disposed on the cooling surface 4a of the cooling device 4, and the screws (not illustrated) inserted into the fastening holes 33a, 33b, 33c, and 33d are screwed into the cooling surface 4a. As a result, as in the second embodiment, stress is applied to the heat dissipation plate 3e, which is consequently flattened as the edge portions 35a1, 35b1, 35c1, and 35d1 of the bottom surface 31b, the edge portions 35a1, 35b1, 35c1, and 35d1 being in contact with the cooling surface 4a, function as the fulcrums. In addition, the bottom surface 31b approaches the cooling surface 4a. Thus, as in the second embodiment, the fifth embodiment achieves reduction of the stress applied to the insulated circuit boards 11, and reduction of the gap between the bottom surface 31b of the heat dissipation plate 3e and the cooling surface 4a. If this gap is reduced, the thickness of the bonding member is also reduced. As a result, the deterioration in heat dissipation is reduced. As in the third embodiment, these cutout portions 35a, 35b, 35c, and 35d may be formed in the heat dissipation plate 3d according to the fourth embodiment.

### Modification 5-1 of Fifth Embodiment

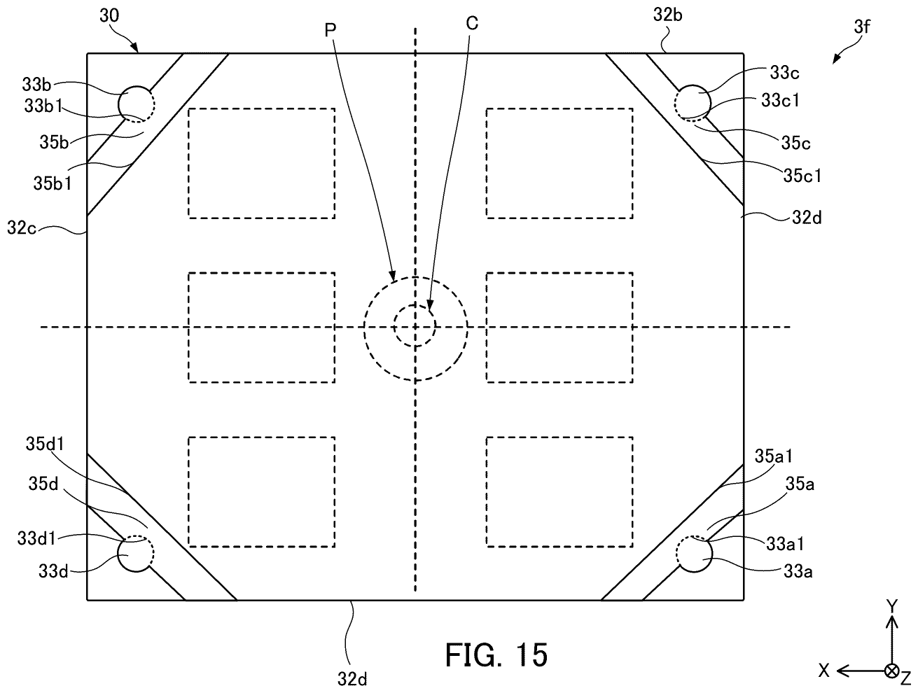

A heat dissipation plate 3f according to modification 5-1 includes cutout portions 35a, 35b, 35c, and 35d different from those of the heat dissipation plate 3e according to the fifth embodiment. The heat dissipation plate 3f according to modification 5-1 will be described with reference to FIG. 15. FIG. 15 is a plan view (a bottom surface) of a heat dissipation plate of a semiconductor device according to the fifth embodiment (modification 5-1).

The edge portions 35a1, 35b1, 35c1, and 35d1 of the cutout portions 35a, 35b, 35c, and 35d of the heat dissipation plate 3f are wider than those of the heat dissipation plate 3e according to the fifth embodiment. In this way, when the heat dissipation plate 3f is fastened with screws, the edge portions 35a1, 35b1, 35c1, and 35d1 are able to support the heat dissipation plate 3f stably.

By using the heat dissipation plate 3f as described above, as is the case with the heat dissipation plate 3e, the stress applied to the insulated circuit boards 11 bonded to the top surface 31a is reduced. In addition, the gap between the bottom surface 31b and the cooling surface 4a is reduced more securely, compared with the gap formed when the heat dissipation plate 3a is used.

According to the disclosed technique, occurrence of damage at fastening and deterioration in heat dissipation are reduced.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit board; and
a heat dissipation plate having a plate shape, having a top surface and a bottom surface, at least the bottom surface having a center portion that protrudes in an upward direction at a center of the heat dissipation plate, having a downward slope from the center portion to an outer edge of the heat dissipation plate, the top surface having a sloping area on which the insulated circuit board is bonded, the heat dissipation plate having a fastening hole that extends through the top surface and the bottom surface in a peripheral area of the heat dissipation plate,
wherein a peripheral portion of the bottom surface of the heat dissipation plate, provided between the outer edge and the fastening hole, is provided at a position that is downward relative to an inner portion of an opening edge of the fastening hole, the inner portion of the opening edge lying on a line passing through the center of the heat dissipation plate and a center of the fastening hole.

2. The semiconductor device according to claim 1, wherein the peripheral area of the heat dissipation plate includes a downwardly projecting protrusion that projects downward from the bottom surface of the heat dissipation plate.

3. The semiconductor device according to claim 2, wherein the protrusion is provided between the fastening hole and the outer edge.

4. The semiconductor device according to claim 1, wherein the inner portion of the opening edge is recessed such that a position thereof is upward relative to the peripheral portion of the bottom surface.

5. The semiconductor device according to claim 4, wherein the heat dissipation plate includes a downwardly projecting protrusion at the peripheral area of on the bottom surface thereof, the peripheral portion of the bottom surface being provided at a bottom of the protrusion.

6. The semiconductor device according to claim 1,
wherein in a plan view of the semiconductor device, the heat dissipation plate has a pair of opposite first edges that extends in a longitudinal direction and a pair of opposite second edges that extends in a lateral direction, one of the pair of opposite second edges being the outer edge of the heat dissipation plate,
wherein the fastening hole is provided in a center of each of the second edges, and
wherein the heat dissipation plate protrudes upward around a center line that is parallel to the pair of second edges and that passes through the center portion.

7. The semiconductor device according to claim 1, wherein the insulated circuit board includes an insulating plate, a conductive circuit pattern provided on a top surface of the insulating plate, and a metal plate provided on a bottom surface of the insulating plate.

8. The semiconductor device according to claim 1,
wherein in a plan view of the semiconductor device, the heat dissipation plate has a pair of opposite first edges that extends in a longitudinal direction and a pair of opposite second edges that extends in a lateral direction, one of the pair of opposite second edge being the outer edge of the heat dissipation plate, and
wherein the fastening hole is provided in each of four corner portions formed by a respective one of the first edges and a respective one of the second edges.
